(19) United States
(12) Patent Application Publication
(10) Pub. No.: US 2004/0188818 A1
(43) Pub. Date: Sep. 30, 2004

(54) Multi-chips module package

(75) Inventor: Sung-Fei Wang, Kaohsiung (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/807,153

(22) Filed: Mar. 24, 2004

(30) Foreign Application Priority Data
Mar. 25, 2003 (TW) 092106681

(51) Int. Cl. H01L 23/48

(52) U.S. Cl. 257/685; 257/690

(57) ABSTRACT

A multi-chips module package comprises a main substrate, a first chip, a second chip, a die-substrate, a plurality of electrically conductive wires and an encapsulation. The first chip and the second chip are respectively electrically connected to the main substrate via the electrically conductive wires, and the first chip is electrically connected to the second chip through the die-substrate. In such a manner, the thickness of the multi-chips module package will be reduced and the path of the electrical signal transmission will be shortened to enhance electrical performance.

### BACKGROUND OF THE INVENTION

1. Field of Invention

This invention relates to a multi-chips module package. More particularly, the present invention is related to a multi-chips module package with an interconnection substrate therein for reducing the thickness of the overall package and enhancing electrical performance of the package.

2. Related Art

As we know, in the semiconductor industries, the manufacture of semiconductors mainly comprises the manufacture of wafers and the assembly of integrated circuits devices. Therein, the integrated circuits (ICs) devices are completely formed by the processes of forming integrated circuits devices on the semiconductor wafers, sawing the wafers into individual integrated circuits devices, placing the individual integrated circuits devices on the substrates, electrically connecting the integrated circuits devices to the substrates respectively and encapsulating the integrated circuits devices and substrates to form a plurality of individual assembly packages. Due to the encapsulation covering the integrated circuits devices, the integrated circuits devices are able to be protected from the damp entering therein. In addition, the individual assembly packages may further provide external terminals for connecting to printed circuit board (PCB).

However, recently, integrated circuits packaging technology is becoming a limiting factor for the development in packaging integrated circuits devices of higher performance. Semiconductor package designers are struggling to keep pace with the increase in pin count, size limitations, low profile, and other evolving requirements for packaging and mounting integrated circuits.

Due to the assembly package in miniature and the integrated circuits operation in high frequency, MCM (multi-chips module) packages are commonly used in said assembly packages and electronic devices. Usually, said MCM package mainly comprises at least two chips encapsulated therein, for example a processor unit, a memory unit and related logic units, so as to upgrade the electrical performance of said assembly package. In addition, the electrical paths between the chips in said MCM package are short so as to reduce the signal delay and save the reading and writing time.

Generally speaking, as shown in FIG. 1, it illustrates a cross-sectional view of a conventional multi-chips module package. Therein, said multi-chips module package 100 mainly comprises a substrate 110, two chips 130 and 150, an encapsulation 170, a plurality of electrically conductive wires 180 and 182, and a plurality of solder balls 184. The substrate 110 has an upper surface 112, a lower surface 114, chip pads 115 and 116 formed on the upper surface 112 for carrying the chips 130 and 150, a plurality of contacts 117 and 118 located on the upper surface 112, and ball pads 119 disposed on the lower surface 114. The chip 130 has an active surface 132 and a back surface 134 opposite to the active surface 132. Furthermore, there are bonding pads 136 formed at the periphery of the active surface 132 of the chip 130. And the chip 130 is attached onto the chip pad 115 through an adhesive layer 140. Besides, the chip 150 also has an active surface 152 and a back surface 154 opposite to the active surface 152. Furthermore, there are bonding pads 156 formed at the periphery of the active surface 152 of the chip 150. And the chip 150 is attached onto the chip pad 116 through an adhesive layer 160.

As mentioned above, the chip 130 and the chip 150 are electrically connected to each other through the wire 180. Therein, an end of the wire 180 is bonded to the bonding pad 136 of the chip 130 and the other end is bonded to the bonding pad 156 of the chip 150; and the chips 130 and 150 are electrically connected to the substrate 110 separately through the wires 182 by bonding the ends of the wires 182 to the bonding pads 138 and 158, and bonding the other ends of the wires 182 to the contacts 117 and 118 of the substrate 110.

In addition, the encapsulation 170 covers the chips 130 and 150, the upper surface 112 of the substrate 100, the wires 180 and 182; and solder balls 184 are disposed on the ball pads 119 of the substrate 110.

In said multi-chips module package 100, the chips 130 and 150 are electrically connected to each other by the wire 180. However, the wire 180 shall be formed in a pre-determined shape so as to keep the stiffness of the wire 180 and prevent said wire 180 from collapsing and sweeping by encapsulation when encapsulating the chips. Accordingly, the length of the wire 180 shall be increased and the top of the wire 180 shall be higher in order to form the pre-determined shape to keep the stiffness of the wire 180. Consequently, the thickness of the package will be increased due to larger distance between the chips 130 and 150. Besides, due to the larger length of the wire 180, the path for transmitting the electrical signal will be increased. Thus, it causes the signal delayed and lowers the electrical performance.

Therefore, providing another assembly package to solve the mentioned-above disadvantages is the most important task in this invention.

### SUMMARY OF THE INVENTION

In view of the above-mentioned problems, an objective of this invention is to provide a multi-chips module package with an interconnection substrate therein to replace the wires. In such a manner, not only the performance of transmitting the electrical signal from one chip to another one is increased but also the manufacture of the assembly packaging will be simplified.

To achieve the above-mentioned objective, a multi-chips module package is provided, wherein the multi-chips module package mainly comprises a main substrate, a first chip, a second chip, an interconnection substrate, a plurality of bumps, a plurality of electrically conductive wires and an encapsulation. Therein, the main substrate has an upper surface and a plurality of contacts formed on the upper surface; the first chip has a first active surface, a first back surface opposite to the first active surface, a first wire-bonding pad and a first bump-bonding pad formed on the first active surface, wherein the first chip is placed on the main substrate and electrically connected to the main substrate through the wires; the second chip has a second active surface, a second back surface opposite to the second active surface, a second wire-bonding pad and a second bump-bonding pad formed on the second active surface, wherein the second chip is placed on the main substrate and electrically connected to the main substrate through the wires; the interconnection substrate has a first chip-connecting contact, a second chip-connecting contact and an electrically conductive circuit connecting the first chip-connecting contact and the second chip-connecting contact, wherein the interconnection substrate is disposed above the first chip and the second chip, and electrically connected to the first chip and the second chip through bumps; the wires electrically connect the main substrate and the first chip and the second chip separately through bonding the wires to the first wire-bonding pad, the second wire-bonding pad and the contacts; and the encapsulation covers the first chip, the second chip, the interconnection substrate, the wires and the upper surface of the main substrate.

In summary, this invention is related to a multi-chips module package with an interconnection substrate therein for electrically connecting the first chip and the second chip to replace the wires. In such a manner, it not only makes the thickness of the package smaller, but also reduces the distance of transmitting the electrical signals from one chip to another chip. Accordingly, the electrically performance of the package will be increased and the package will becomes smaller and thinner.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of the conventional multi-chips module package;

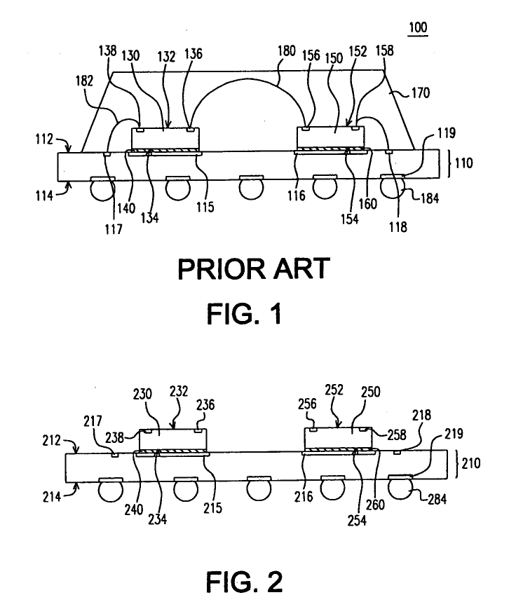

FIGS. 2 to 5 are enlarged cross-sectional views showing the progression of steps for forming a multi-chips module package according to the preferred embodiment of this invention;

FIG. 6 is a cross-sectional view of multi-chips module package according to another preferred embodiment; and

FIG. 7 is a cross-sectional view of multi-chips module package according to another preferred embodiment.

### DETAILED DESCRIPTION OF THE INVENTION

The multi-chips stacked package according to the preferred embodiments of this invention will be described herein below with reference to the accompanying drawings, wherein the same reference numbers refer to the same elements.

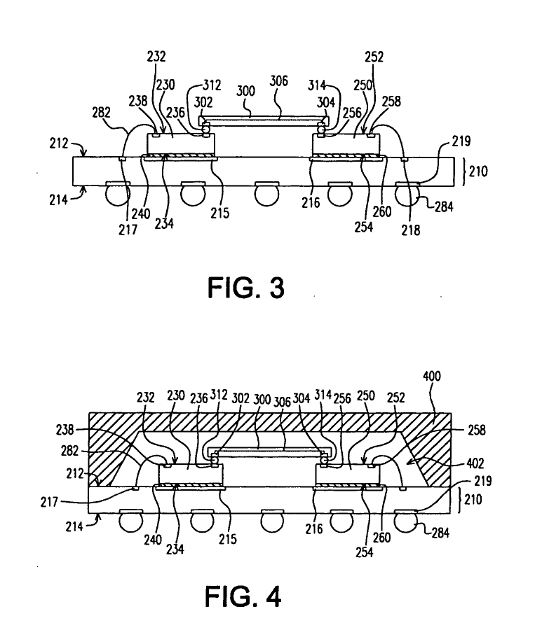

FIGS. 2 to 5 are enlarged cross-sectional views showing the progression of steps for forming a multi-chips module package according to the preferred embodiment of this invention.

As shown in FIG. 2, firstly, a main substrate 210 is provided, wherein the main substrate 210 has an upper surface 212, a lower surface 214, two chip pads 215 and 216, a plurality of contacts 217 and 218 formed on the upper surface 212 and a plurality of ball pads 219 formed on the lower surface 214. Next, a first chip 230 and a second chip 250 are provided to place on the upper surface 212 of the main substrate 210 and attach onto the chip pads 215 and 216 respectively through adhesive layers 240 and 260. Therein, the first chip 230 has a first active surface 232, a first back surface 234 opposite to the first active surface 232, and bump-bonding pads 236 and wire-bonding pads 238 located at the periphery of the first active surface 232 of the chip 230; and the second chip 250 has a second active surface 252, a second back surface 254 opposite to the second active surface 252, and bump-bonding pads 256 and wire-bonding pads 258 located at the periphery of the second active surface 252 of the second chip 250.

Then, referring to FIG. 3, an interconnection substrate 300 is provided to attached on the first chip 230 and the second chip 250, wherein the interconnection substrate 300 has chip-connecting contacts 302 and 304 and a circuit 306 electrically connecting the chip-connecting contact 302 and the chip-connecting contact 304, and the chip-connecting contacts 302 and 304 are electrically connected to the first chip 230 and the second chip 250 through bumps 312 and 314. It should be noted that the interconnection substrate 300 can be a die-substrate and the circuit 306, the chip-connecting contacts 302 and 304 can be formed in the wafer by the wafer manufacture technology or formed on the upper surface of the die-substrate by the process of development, photolithography, etching, and etc. Moreover, the bumps 312 mentioned above comprise metal bumps, solder bumps, gold bumps, bumps and electrically conductive plastic bumps, wherein each said plastic made of epoxy core with a metal layer thereon.

Afterwards, a wire-bonding process is performed to have the first chip 230 and the second chip 250 electrically connected to the main substrate 210 through the electrically conductive wires 282 separately. Therein, one end of one of the electrically conductive wires 282 is bonded to the wire-bonding pad 238 of the first chip 230 and another end of the wire 282 is connected to the contact 217. Similarly, another wire 282 connects the wire-bonding pad 258 of the second chip 250 to the contact 218 of the main substrate 210.

Next, referring to FIG. 4 and FIG. 5, firstly, a mold apparatus 400 having a mold chase 402 is provided and the semi-finished package including the first chip 230, the second chip 250 and the main substrate 210 carrying the chips 230 and 250 are placed in the mold chase 402. Then, an encapsulation (mold compound) 270 is filled in the mold chase 402 to encapsulate the chips 230 and 250, and to cover the main substrate 210 and the wires 282. After the encapsulation is hardened and the mold apparatus is removed, the encapsulation process is completely performed.

The interconnection substrate 300 is provided to replace the wires connecting the first chip 230 to the second chip 250 so as to reduce the thickness of the package. In addition, it can make the path of transmitting the electrical signal smaller and smaller so as to reduce the loss of the electrical signals and enhance the electrical performance.

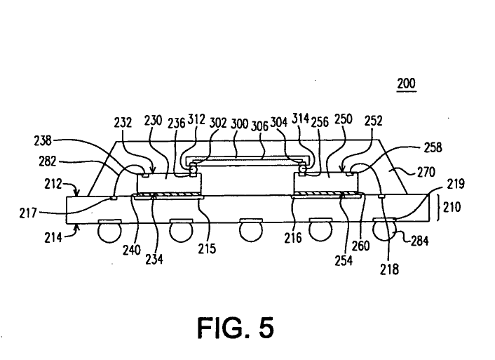

Next, referring to FIG. 6, which illustrates a multi-chips module package according to another embodiment formed according to the processes shown as above. Therein the multi-chips module package comprises a main substrate 210, a first chip 230, a second chip 250, an encapsulation 270, an interconnection substrate 300 and a plurality of wires 282.

As mentioned above, the main substrate 210 has an upper surface 212 and a lower surface 222, and the main substrate 210 further has two chip pads 215 and 216, a plurality of contacts 217 and 218 formed on the upper surface 212, and ball pads 219 formed on the lower surface 222.

The first chip 230 has a first active surface 232 and a first back surface 242 opposite to the first active surface 232. Furthermore, the first chip 230 has a plurality of bump-bonding pads 236 and wire-bonding pads 238 located at the periphery of the first active surface 232. In addition, the first chip 230 is placed on the chip pad 215 of the main substrate 210 through an adhesive layer 240. Similarly, the second chip 250 has a plurality of bump-bonding pads 256 and wire-bonding pads 258 located at the periphery of the second active surface 252. In addition, the second chip 250 is placed on the chip pad 216 of the main substrate 210 through an adhesive layer 260.

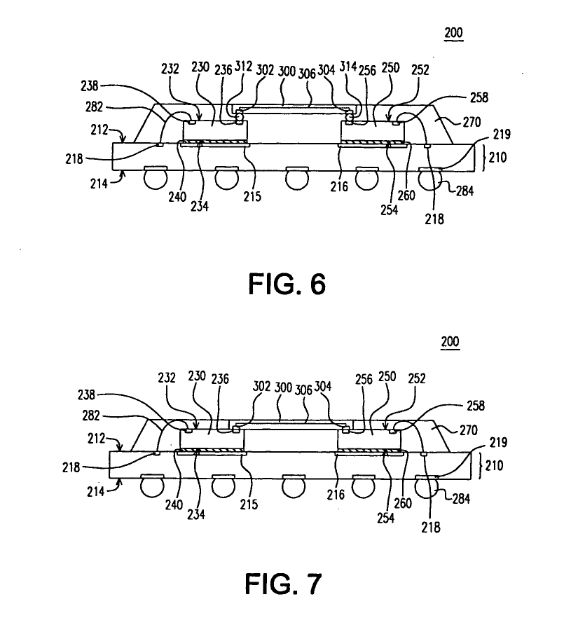

Besides, the interconnection substrate 300 has chip-connecting contacts 302 and 304, and a circuit electrically connecting the chip-connecting contacts 302 and 304. The interconnection is attached to and electrically connected to the first chip 230 and the second chip 250 through bonding the chip-connecting contacts 302 and 304 to the corresponding bump-bonding pads 302 and 304 separately by bumps 236 and 256. And the interconnection substrate 300 is exposed out of the encapsulation 270 so as to increase the thermal performance due to larger area of the exposed dissipation surface. However, as shown in FIG. 7, the interconnection is attached to and electrically connected to the first chip 230 and the second chip 250 through bonding the chip-connecting contacts 302 and 304 to the corresponding bump-bonding pads 302 and 304 directly by solder material, such as solder paste (not shown). In addition, the first chip 230 and the second chip 250 are electrically connected to the main substrate 210 by connecting the wire-bonding pads 236 to the contact 217 and connecting the wire-bonding pad 256 to the contact 218 through the wires 282. Furthermore, the encapsulation 270 covers the first chip 230, the second chip 250, the upper surface 212 of the main substrate 210, and the interconnection substrate 300 and the wires 282. It should be noted that, similarly, the interconnection substrate 300 is exposed out of the encapsulation 270 so as to increase the thermal performance due to larger area of the exposed dissipation surface. Besides, a plurality of solder balls 284 are disposed on the lower surface 214 of the main substrate 210 for connecting to external circuits devices, for example, printed circuit boards. It should be noted that the main substrate 210 may be a lead-frame, for example, a quad flat non-leaded type lead-frame. When the quad flat non-leaded lead-frame is taken for carrying the chips, the multi-chips module can be mounted to external circuits devices directly. In addition, the interconnection substrate may be either an organic substrate or a die-substrate. When the interconnection substrate is a die-substrate formed by wafer manufacture technology, it will be applied to fine-pitch assembly package and a passive component, for example a capacitor, can be formed embedded therein. When the interconnection substrate is an organic substrate, said passive component can be mounted thereon by SMT technology.

Although the invention has been described in considerable detail with reference to certain preferred embodiments, it will be appreciated and understood that various changes and modifications may be made without departing from the spirit and scope of the invention as defined in the appended claims.

What is claimed is:

1. A multi-chips module package, comprising:
a main substrate having an upper surface and a plurality of contacts;
a first chip disposed above the main substrate, the first chip having a first active surface, a first back surface opposite to the first active surface, a first wire-bonding pad and a first bump-bonding pad, wherein the first wire-bonding pad and the first bump-bonding pad are formed on the first active surface;
a second chip disposed above the main substrate, the second chip having a second active surface, a second back surface opposite to the second active surface, a second wire-bonding pad and a second bump-bonding pad, wherein the second wire-bonding pad and the second bump-bonding pad are formed on the second active surface;
an interconnection substrate having a first chip-connecting contact, a second chip-connecting contact and a circuit connecting the first chip-connecting contact and the second chip-connecting contact;
a first bump, the first bump interposed between the first chip-connecting contact and the first bump-bonding pad;
a second bump, the second bump interposed between the second chip-connecting contact and the second bump-bonding pad; and
a plurality of wires, the wires electrically connecting the first wire-bonding pad and the second wire-bonding pad to the contacts respectively.

2. The multi-chips module package of claim 1, further comprising an encapsulation covering the first chip, the second chip, and the upper surface of the main substrate.

3. The multi-chips module package of claim 1, wherein the interconnection substrate is a die-substrate.

4. The multi-chips module package of claim 1, wherein the main substrate is a lead-frame.

5. The multi-chips module package of claim 1, wherein the main substrate is a quad flat non-leaded lead-frame.

6. The multi-chips module package of claim 1, wherein the first bump is a metal bump.

7. The multi-chips module package of claim 1, wherein the second bump is an electrically conductive plastic bump.

8. The multi-chips module package of claim 1, wherein the material of the second bump comprises epoxy.

9. The multi-chips module package of claim 1, wherein the interconnection substrate is an organic substrate.

10. The multi-chips module package of claim 6, wherein the metal bump is a gold bump.

11. The multi-chips module package of claim 6, wherein the metal bump is a lead-free bump.

12. The multi-chips module package of claim 1, wherein the main substrate further comprises two chip pads for carrying the first chip and the second chip.

13. The multi-chips module package of claim 1, further comprising a plurality of solder balls attached to ball pads of the lower surface of the main substrate.

14. The multi-chips module package of claim 1, further comprising a passive component disposed on the interconnection substrate.

15. The multi-chips module package of claim 14, wherein the passive component is a capacitor.

16. The multi-chips module package of claim 1, further comprising a passive component embedded in the interconnection substrate.

17. The multi-chips module package of claim 2, wherein the interconnection substrate is exposed out of the encapsulation.

18. A multi-chips module package, comprising:
a main substrate having an upper surface and a plurality of contacts;
a first chip disposed above the main substrate, the first chip having a first active surface, a first back surface opposite to the first active surface, a first wire-bonding pad and a first bump-bonding pad, wherein the first wire-bonding pad and the first bump-bonding pad are formed on the first active surface;
a second chip disposed above the main substrate, the second chip having a second active surface, a second back surface opposite to the second active surface, a second wire-bonding pad and a second bump-bonding pad, wherein the second wire-bonding pad and the second bump-bonding pad are formed on the second active surface;
an interconnection substrate having a first chip-connecting contact, a second chip-connecting pad and a circuit connecting the first chip-connecting contact and the second chip-connecting contact, the interconnection substrate attached to the first chip and the second chip directly through solder materials; and
a plurality of wires, the wires connecting the first wire-bonding pad and the second wire-bonding pad to the contacts respectively.

19. The multi-chips module package of claim 18, further comprising an encapsulation covering the first chip, the second chip, and the upper surface of the main substrate.

20. The multi-chips module package of claim 18, wherein the interconnection substrate is a die-substrate.

21. The multi-chips module package of claim 20, wherein the interconnection substrate is exposed out of the encapsulation.
